(19) United States
(12) Patent Application Publication
(10) Pub. No.: US 2014/0063920 A1
(43) Pub. Date: Mar. 6, 2014

(54) Static random access memory that initializes to pre-determined state

(71) Applicant: Sterling A. Knickerbocker, Chester, VA (US)

(72) Inventor: Sterling A. Knickerbocker, Chester, VA (US)

(73) Assignee: United States Government, as Represented by the Secretary of the Navy, Arlington, VA (US)

(21) Appl. No.: 13/573,278

(22) Filed: Aug. 28, 2012

(51) Int. Cl. G11C 11/412

(52) U.S. Cl. CPC G11C 11/412
USPC 365/156

(57) ABSTRACT

A static random access memory (SRAM) is provided for establishing an initialization state. The SRAM connects to a plurality of signal lines including a bit line and an inverse bit line. The SRAM includes first and second inverters, a voltage potential and a ground. The first inverter includes a first n-type metal oxide semiconductor (MOS) transistor having a first n-type threshold voltage and a first p-type MOS transistor having a first p-type threshold voltage. The second inverter includes a second n-type MOS transistor having a second n-type threshold voltage and a second p-type MOS transistor having a second p-type threshold voltage. The first transistors connect respectively first n-type and first p-type drains together at a first junction that connects to the bit line. The second transistors connect respectively a second n-type and second p-type drains together at a second junction that connects to the inverse bit line. The voltage potential connects to corresponding first and second p-type sources of the first and second p-type MOS transistors, and the ground potential connects to corresponding first and second n-type sources of the first and second n-type MOS transistors. The SRAM initializes the bit line to either logical high or low in response to differences in threshold voltages between either or both of the first and second n-type MOS transistors or the first and second p-type MOS transistors.

### STATEMENT OF GOVERNMENT INTEREST

The invention described was made in the performance of official duties by one or more employees of the Department of the Navy, and thus, the invention herein may be manufactured, used or licensed by or for the Government of the United States of America for governmental purposes without the payment of any royalties thereon or therefor.

### BACKGROUND

The invention relates generally to initialization of static random access memory (SRAM). In particular, the invention relates to establishing specific default initialized states for SRAM circuits.

Random access memory (RAM) represents various forms of semiconductor circuitry and includes static RAM (SRAM) and dynamic RAM (DRAM). SRAM uses bi-stable latching circuitry to store each bit so as to be maintained until electrical power cutoff, and thus differentiates from DRAM, which must be periodically refreshed. An SRAM exhibits data remembrance, but nonetheless remains volatile in the conventional sense that data are eventually lost when the memory is not powered.

### SUMMARY

Conventional SRAM configurations yield disadvantages addressed by various exemplary embodiments of the present invention. In particular, an SRAM is provided that establishes an initialization state for either logical high or low.

Various exemplary embodiments provide an SRAM that connects to signal lines including a bit line and an inverse bit line for initialization. The SRAM includes first and second inverters, a voltage potential and a ground. The first inverter includes a first n-type metal oxide semiconductor (MOS) transistor (MN1) having a first n-type threshold voltage and a first p-type MOS transistor (MP3) having a first p-type threshold voltage. The second inverter includes a second n-type MOS transistor (MN2) having a second n-type threshold voltage and a second p-type MOS transistor (MP4) having a second p-type threshold voltage. The SRAM initializes the bit line to either logical high or low in response to differences in threshold voltages between either or both of the first and second n-type MOS transistors or the first and second p-type MOS transistors.

In various exemplary embodiments, the first transistors connect respectively a first n-type drain and a first p-type drain together at a first junction (A terminal) that connects to the bit line. The second transistors connect respectively a second n-type drain and a second p-type drain together at a second junction (B terminal) that connects to the inverse bit line. In further embodiments, the voltage potential connects to corresponding first and second p-type sources of the first and second p-type MOS transistors, and the ground potential connects to corresponding first and second n-type sources of the first and second n-type MOS transistors.

In alternate embodiments, the SRAM further includes a word line along with a third n-type MOS transistor (MN5) that connects a third drain at the first junction, a third source at the bit line and a third gate at the word line; and a fourth n-type MOS transistor (MN6) connecting a fourth drain at the second junction, a fourth source at the inverse bit line and a fourth gate at the word line.

### BRIEF DESCRIPTION OF THE DRAWINGS

These and various other features and aspects of various exemplary embodiments will be readily understood with reference to the following detailed description taken in conjunction with the accompanying drawings, in which like or similar numbers are used throughout, and in which:

FIG. 1 is a logic representational view of an SRAM;

FIG. 2 is a schematic view of an inverter circuit;

FIG. 3 is a schematic view of an exemplary 6-transistor (6T) SRAM cell;

FIG. 4 is a schematic view of a simplified variable resistance equivalent circuit with inset of n-type MOS transistor IV curve;

FIG. 5 is a graphical view of simulation results from balanced SRAM initialization;

FIG. 6 is a schematic view of an SRAM circuit that initializes in a high state;

FIG. 7 is a graphical view of simulation results initializing high;

FIG. 8 is a schematic view of an SRAM circuit that initializes in a low state; and

FIG. 9 is a graphical view of simulation results initializing low.

### DETAILED DESCRIPTION

In the following detailed description of exemplary embodiments of the invention, reference is made to the accompanying drawings that form a part hereof, and in which is shown by way of illustration specific exemplary embodiments in which the invention may be practiced. These embodiments are described in sufficient detail to enable those skilled in the art to practice the invention. Other embodiments may be utilized, and logical, mechanical, and other changes may be made without departing from the spirit or scope of the present invention. The following detailed description is, therefore, not to be taken in a limiting sense, and the scope of the present invention is defined only by the appended claims.

In accordance with a presently preferred embodiment of the present invention, the components, process steps, and/or data structures may be implemented using various types of operating systems, computing platforms, computer programs, and/or general purpose machines. In addition, those of ordinary skill in the art will readily recognize that devices of a less general purpose nature, such as hardwired devices, or the like, may also be used without departing from the scope and spirit of the inventive concepts disclosed herewith. General purpose machines include devices that execute instruction code. A hardwired device may constitute an application specific integrated circuit (ASIC) or a field-programmable gate array (FPGA) or other related component, such as produced from a metal oxide semiconductor (MOS). Such components can yield a field effect transistor (FET), and such a device composed from doped semiconductor may be referenced as a MOSFET.

Various exemplary embodiments provide an SRAM cell design that consistently initializes to the same predetermined state after each power cycle. An exemplary SRAM can be employed at system start-up as bootable code and subsequently as random access memory (RAM) for read/write access. Due to loss of data when not powered, SRAM has limited utility until initialized by the incorporating circuitry. Utilizing the design and process described in exemplary embodiments, the SRAM initializes to a predetermined state that can contain data and/or instructions that are available for immediate execution upon power-up, but nonetheless afterwards be overwritten with new data.

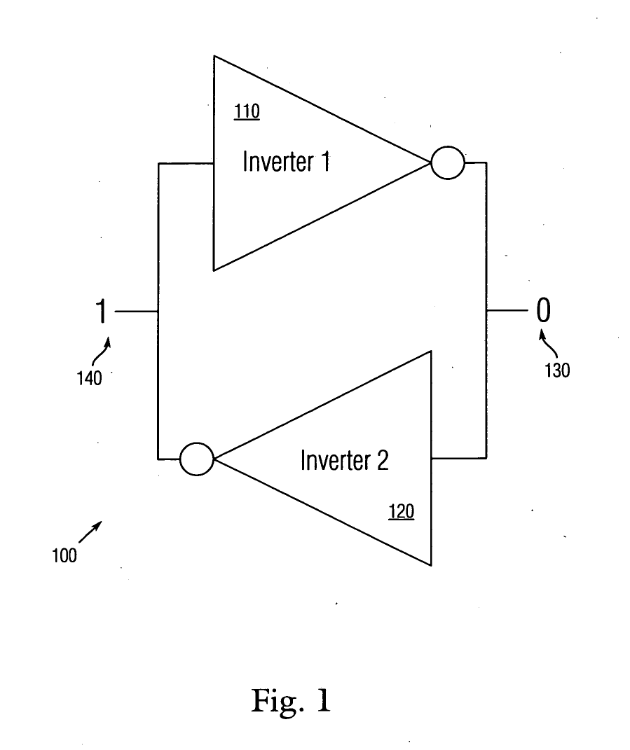

FIG. 1 shows a schematic view 100 of an inverter logic circuit that includes inverter-1 110 connecting to inverter-2 120. A zero (0 or low) register 130 constitutes the output of inverter-1 110 and the input to inverter-2 120. A one (1 or high) register 140 constitutes the output of inverter-2 120 and the input to inverter-1 110. This logic circuit can be produced in electrical component hardware.

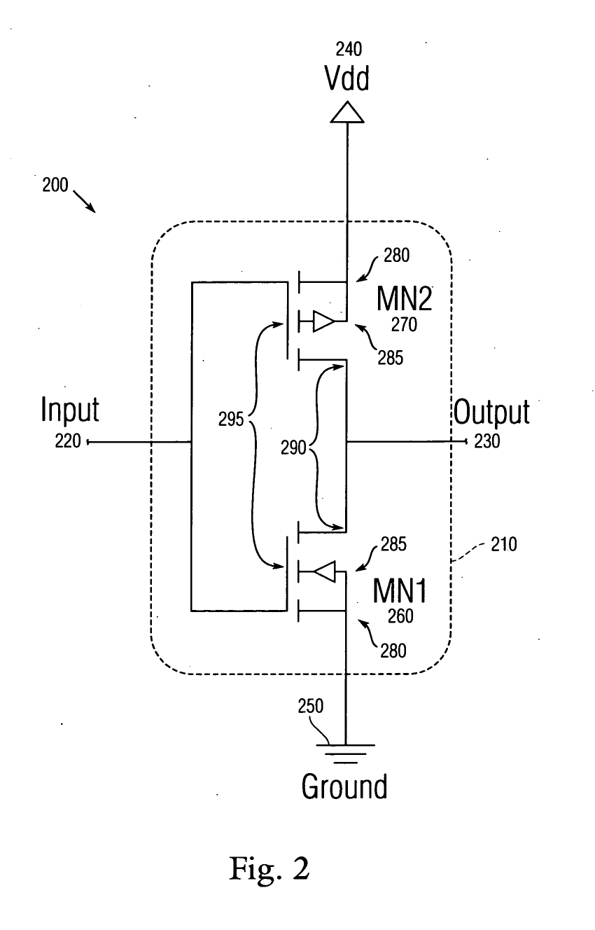

FIG. 2 shows a schematic view 200 of a logical inverter 210 using transistors. Each inverter 210 in schematic view 100 comprises a p-type metal oxide semiconductor (pMOS) transistor and an n-type metal oxide semiconductor (nMOS) transistor, each with four terminals: source, body, drain and gate. The n-type and p-type transistors incorporate respectively negative and positive relative doping of the source and drain compared to the substrate onto which these components are fabricated. The inverter 210 (usable in a memory module) receives an input 220 and yields an output 230, being connected to a driver voltage potential V_{dd} 240 and ground 250. For an inverter design, the output 230 will be the converse (e.g., inverse) of the input 220.

The inverter 210 includes a first n-type transistor MN1 260 and a second p-type transistor MP2 270. The terminals for these transistors include source 280, body 285, drain 290 and gate 295. These transistor designs connect the source 280 and body 285 together. The input 220 applies to gates 295 of the transistors MN1 260 and MP2 270. The output 230 connects to drains 290 for transistors MN1 260 and MP2 270. For the example shown, the potential V_{dd} 240 connects to the source 280 and body 285 of transistor MP2 270; and ground 250 connects to the source 280 and body 285 of transistor MN1 260.

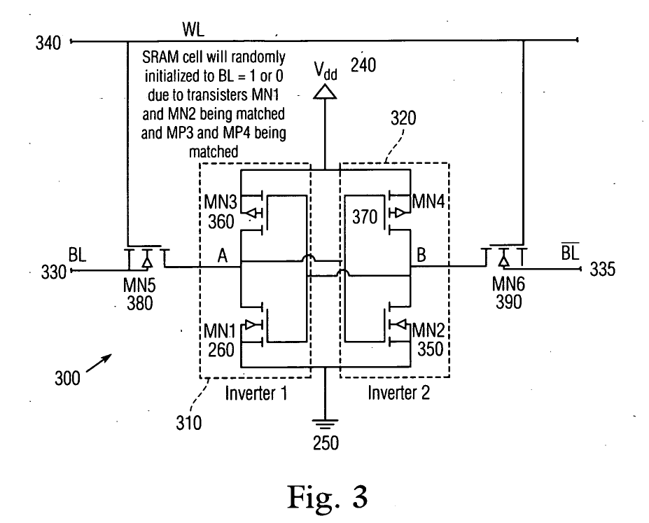

FIG. 3 shows a schematic view 300 of a 6T SRAM unit cell or circuit that connects to potential V_{dd} 240 and ground 250. A first inverter 310 connects to a second inverter 320 and arranged on a circuit with a bit line BL 330, an inverse bit line B̅L̅ 335 and a word line WL 340. The first inverter 310 includes the first n-type transistor MN1 260 and a third p-type transistor MP3 360; the second inverter 320 includes a second n-type transistor MN2 350 and a fourth p-type transistor MP4 370. The state of an SRAM cell is determined by the voltage at the A terminal.

The first inverter 310 connects at an A terminal to the BL line 330 via a fifth n-type transistor MN5 380. The second inverter 320 connects at a B terminal to the inverse bit line B̅L̅ 335 via a sixth n-type transistor MN6 390. The gates of transistors MN1 260 and MP3 360 connect to the B terminal of the second inverter 320. The gates of transistors MN2 350 and MP4 370 connect to the A terminal of the first inverter 310. The drains of transistors MN1 260, MP3 360 and MN5 380 connect to the A terminal. The drains of transistors MN2 350, MP4 370 and MN6 390 connect to terminal B.

The gates of transistors MN5 380 and MN6 390 connect to the WL line 340. (Recall that their respective sources connect to the BL line 330 and the inverse bit line B̅L̅ line 335, whereas their respective drains connect to the A and B terminals.) When balanced, the SRAM cell in schematic view 300 initializes to a common state between V_{dd} 240 and ground 250 (i.e., voltage at terminal A is equal to voltage at terminal B) due to the transistors MN1 260 and MN2 350 having matched design parameters (e.g., length, width, threshold voltage, etc.), and transistors MP3 360 and MP4 370 having matched design parameters (e.g., length, width, threshold voltage, etc.).

Due to manufacturing variation, slight differences in the pMOS or nMOS transistors shown in schematic view 300 result, which causes the SRAM cell to initialize to a random state of either high (binary equivalent of a “1”) or low (binary equivalent of a “0”). Conventionally, this result cannot be controlled or manipulated by the designer and constitutes a sole function of the slight electrical characteristics of the transistors that comprise the SRAM cell.

Various exemplary embodiments intentionally modify at least one of the basic transistors that comprise the SRAM unit cell to create an intentionally “unbalanced” circuit. This causes the state to reach a predetermined high or low output, thereby providing full control to the designer over how the SRAM initializes at power-up. This enables the SRAM to operate in a manner similar to read-only memory (ROM) at system initialization (boot up) and during system execution as random access memory (RAM).

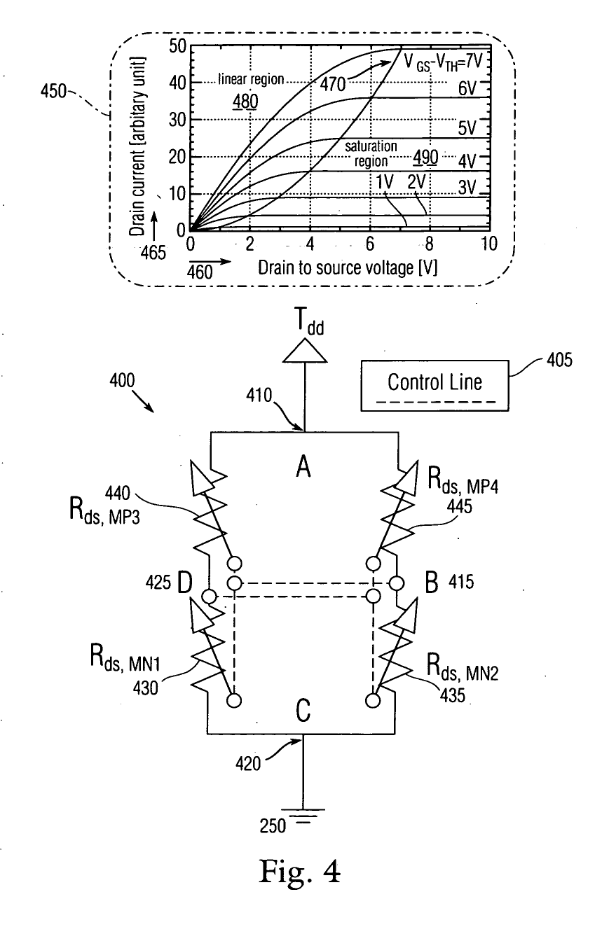

FIG. 4 shows a schematic view 400 of a variable resistance circuit representing the equivalent of the SRAM unit cell operating in the ohmic (or linear) region that connects to potential V_{dd} 240 and ground 250. A legend 405 identifies the dash-line connections as control lines, in contrast to the solid lines that transmit electric current. The circuit includes junctions A 410, B 415, C 420 and D 425 with variable resistors connected in series or parallel. The electrical resistors include R_{ds,MN1} 430 between junctions C 420 and D 425, R_{ds,MN2} 435 between junctions B 415 and C 420, R_{ds,MP3} 440 between junctions D 425 and A 410, and R_{ds,MP4} 445 between junctions B 415 and A 410. The voltage at junction B 415 controls variability of the resistors R_{ds,MN1} 430 and R_{ds,MP3} 440. The voltage at junction D 425 controls variability of the resistors R_{ds,MN2} 435 and R_{ds,MP4} 445.

An insert graph 450 illustrates an n-channel metal-oxide-semiconductor field effect transistor (MOSFET) that exhibits electric current response to voltage, as with the variable resistance circuit in schematic view 400. The abscissa 460 represents voltage between drain 290 and source 280, and the ordinate 465 represents drain current. Various response curves plotted for select voltage between gate 295 and source 280 show current rise and plateau to a constant value. A locus curve 470 distinguishes the ohmic or linear region 480 of rising current from the current saturation region 490 leveling to steady-state. The transistor behaves as a resistor in the ohmic region 480, and as a switch in the saturation region 490.

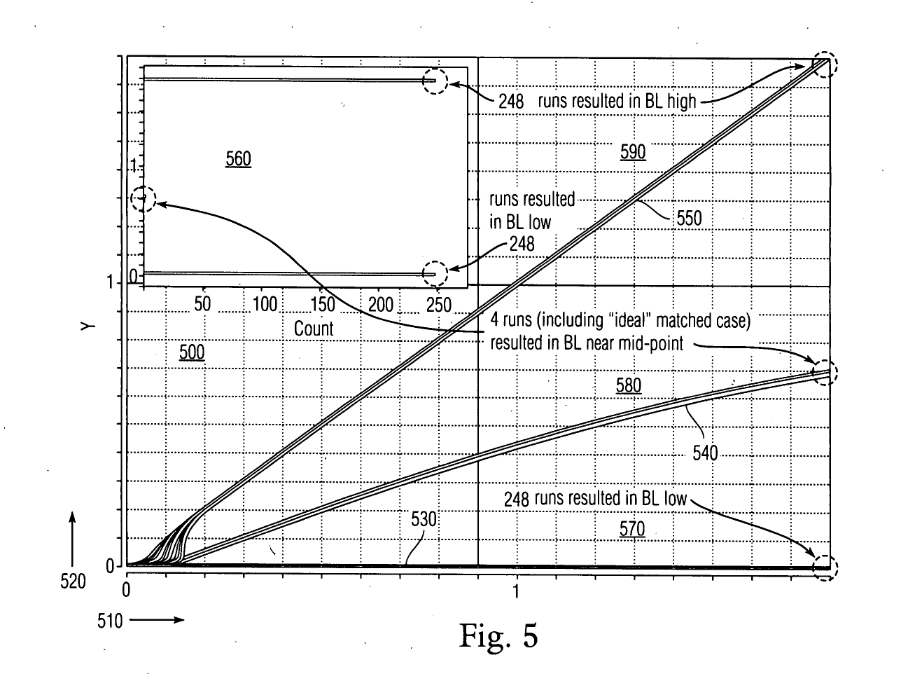

FIG. 5 shows a graphical view 500 of a Monte Carlo (i.e., random) statistical simulation series for a balanced initialization for the standard SRAM cell. The abscissa 510 represents V_{dd} 240 as input, and the ordinate 520 represents output voltage of the bit line BL 330. The simulation data (for five-hundred executions) show a low voltage curve 530, a mid voltage curve 540 and a high voltage curve 550. An insert graph 560 includes voltage with respect to simulation count. A first collection of 248 executions resulted in a low BL condition 570 at the bottom right. A second collection of four executions resulted in near mid-point BL condition 580. A third collection of 248 executions resulted in a high BL condition 590 at the top right.

Consequently, approximately half the simulations result in a high output while approximately half the simulations result in a low output, as expected. For ideal (i.e., balanced) components, the SRAM cell should typically yield bit line voltages near mid-point. However, component fabrication variability induces random biases that unpredictably set the bit line voltage to either the high or low value.

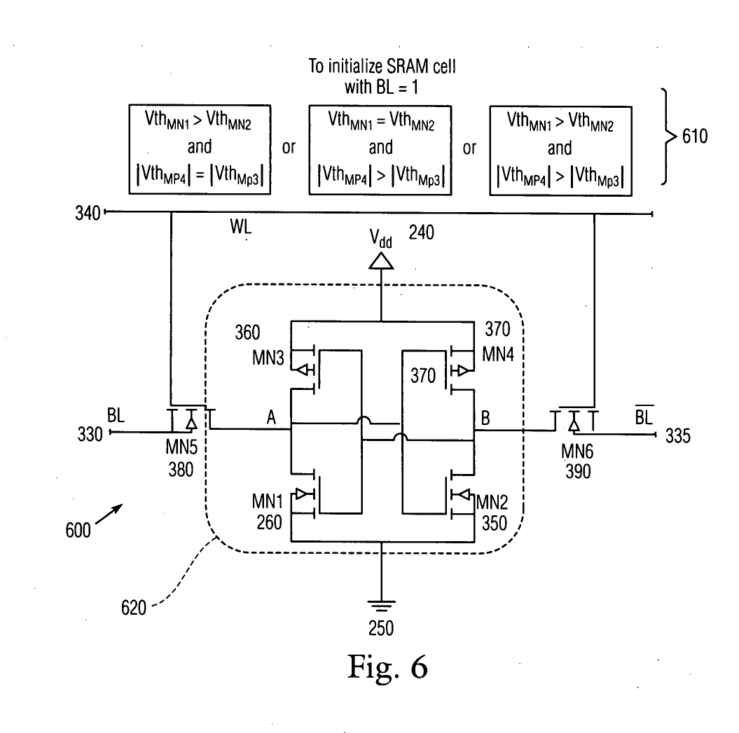

FIG. 6 shows a schematic view 600 of an SRAM circuit designed to initialize the SRAM with high bit line BL=1 based on a set of logical conditions 610 for threshold voltage Vₜₕ across transistors. The conditions 610 include {V_{th,MN1}>V_{th,MN2} .AND. |V_{th,MP4}|=|V_{th,MP3}|} .OR. {V_{th,MN1}=V_{th,MN2} .AND. |V_{th,MP4}|>|V_{th,MP3}|} .OR. {V_{th,MN1}>V_{th,MN2} . AND. |V_{th,MP4}|>|V_{th,MP3}|}. This can be interpreted as an inclusive “either” condition with an unbalance between MN1 260 and MN2 350 and/or between MP3 360 and MP4 370.

A high voltage initialization circuit 620 connects to potential V_{dd} 240 and ground 250. The circuit 620 includes transistors MN1 260, MN2 350, MP3 360 and MP4 370, and connects to bit line BL 330, inverse bit line B̅L̅ 335 and word line WL 340 via transistors MN5 380 and MN6 390. The drains, sources and gates connect together in the manner described for view 300, with the SRAM circuit combining the inverter circuits 310 and 320.

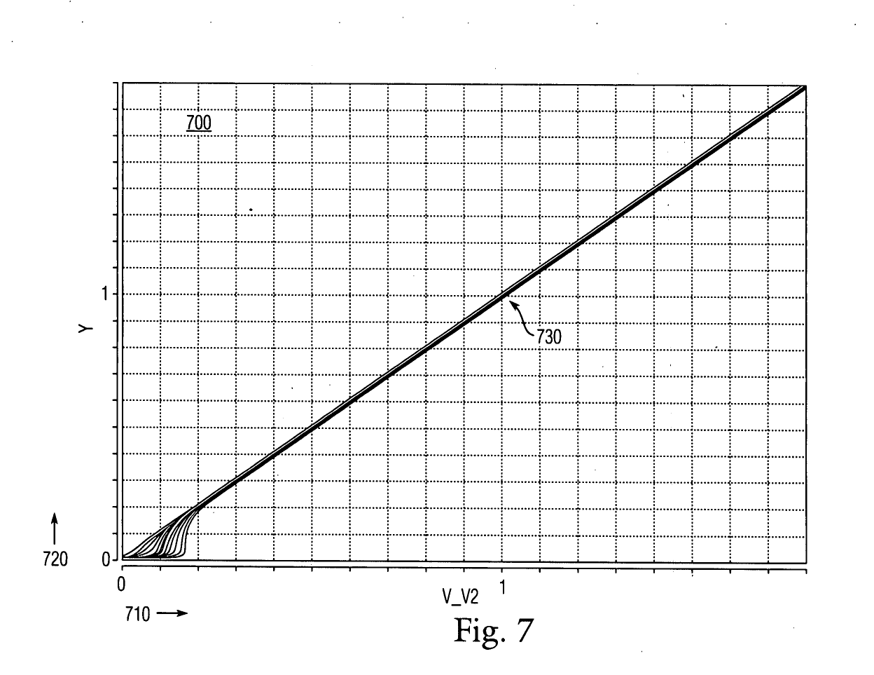

FIG. 7 shows a graphical view 700 of a Monte Carlo statistical simulation series for a high-state initialization. The abscissa 710 represents V_{dd} 240 as input voltage, and the ordinate 720 represents output voltage of the bit line BL 330. A series of lines 730 extend from bottom left to upper right denoting high bit line BL=1, based on 1500 simulations. The graph view 700 exemplifies the linear correlation between input and output voltages above input voltage of 0.2V for this example.

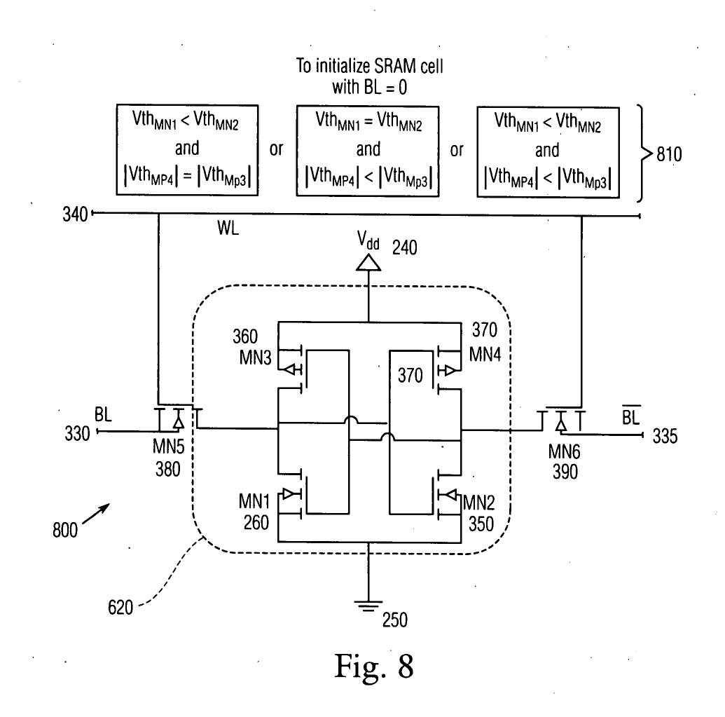

FIG. 8 shows a schematic view 800 of an SRAM circuit designed to initialize the SRAM with low bit line BL=0 based on a set of logical conditions 810 for threshold voltage Vₜₕ across the transistors. The conditions 810 include {V_{th,MN1}≦V_{th,MN2} .AND. |V_{th,MP4}|=|V_{th,MP3}|} .OR. {V_{th,MN1}=V_{th,MN2} .AND. |V_{th,MP4}|<|V_{th,MP3}|} .OR. {V_{th,MN1}<V_{th,MN2} . AND. |V_{th,MP4}|<|V_{th,MP3}|}. This can also be interpreted as an inclusive “either” condition with an unbalance between MN1 260 and MN2 350 and/or between MP3 360 and MP4 370.

A low voltage initialization circuit 620 connects to V_{dd} 240 and ground 250. The circuit 620 includes transistors MN1 260, MN2 350, MP3 360 and MP4 370, and connects to bit line BL 330, inverse bit line B̅L̅ 335 and word line WL 340 via transistors MN5 380 and MN6 390. The drains, sources and gates connect together in the manner described for schematic view 300, with the SRAM circuit combining the inverter circuits 310 and 320.

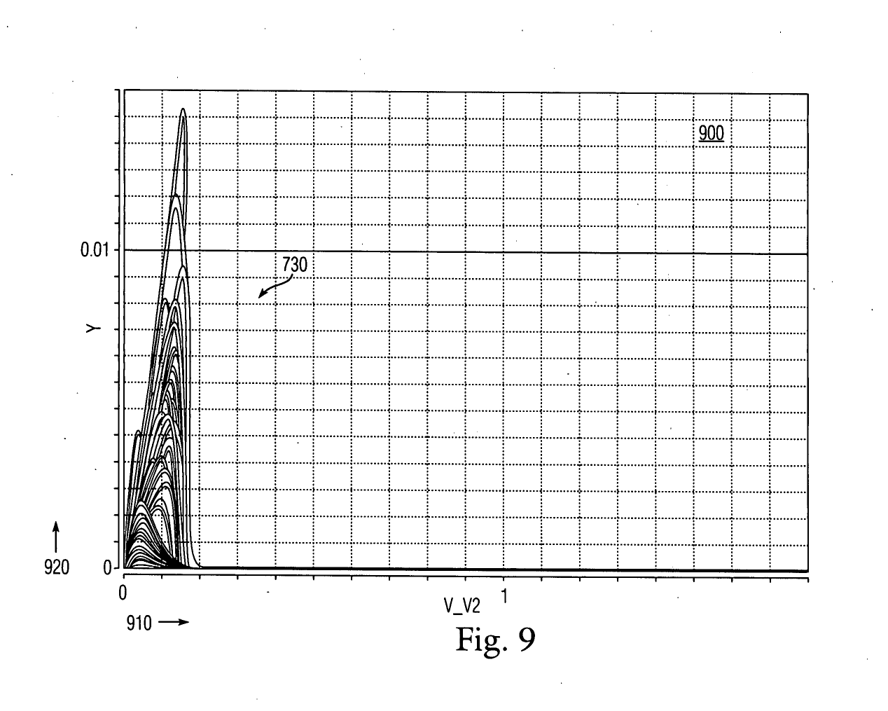

FIG. 9 shows a graphical view 900 of a Monte Carlo statistical simulation series for a low-state initialization. The abscissa 910 represents V_{dd} 240 as input voltage, and the ordinate 920 represents output of the bit line BL 330. A series of lines 930 extend from bottom left upward before transitioning to bottom right denoting low bit line BL=0, based on 1500 simulations. This highlights the brief linear operation of the SRAM in the transistor ohmic region 480 for very low values of V_{dd} 240, before reaching the saturation region 490. The graph 900 exemplifies that output voltages trends below 0.01V above input voltage of 0.2V for this example.

In a balanced SRAM cell during initialization (power-up), the four metal oxide semiconductor (MOS) transistors behave very similar to a Wheatstone bridge while in the ohmic (or linear) region of operation (equivalent circuit shown in schematic view 400). For transistors that are exactly matched, the voltage difference between junctions B and D remains 0V and the cell stabilizes at some quiescent operating point based on the resistances roughly equivalent to

$$\frac{{R}_{ds , MN 1}}{{R}_{ds , MN 2} + {R}_{ds , MN 1}} \times {V}_{dd} .$$

However, due to slight variances in the manufacturing process that cannot be avoided, the transistors do not perfectly match. Thus the voltage at junction B rises at a different rate than the voltage at junction D. As the voltage at junctions B and D rises, this affects voltages at the gates of the transistors in the opposite leg of the unit cell, which in turn influence the effective resistance of the Wheatstone bridge.

Due to this imbalance in the circuit, the unit cell will eventually snap into a state where the voltage at junction B is either high (roughly equivalent to potential V_{dd} 240) or low (roughly equivalent to ground 250) and junction D snaps to the opposite state. Because the designer cannot control these slight imperfections in manufacturing, the designer cannot predict which state the SRAM cell initializes to upon power-up. Roughly half of the cells will initialize to a logical 1 (BL high) and about one-half will initialize to a logical 0 (BL low) as shown in the model data of plot view 500.

In order to intentionally initialize the SRAM unit cell with a defined state, the designer must explicitly mismatch select transistors and thereby unbalance the circuit in the schematic view 400. There are many methods with which to unbalance the circuit by altering threshold voltage or electrical resistance, some of which include:

(a) MN1 260 and MN2 350 mismatched channel length L,

(b) MN1 260 and MN2 350 mismatched device width W,

(c) MP3 360 and MP4 370 mismatched channel length L,

(d) MP3 360 and MP4 370 mismatched device width W,

(e) MN1 260 and MN2 350 mismatched threshold voltage Vₜₕ,

(f) MP3 360 and MP4 370 mismatched threshold voltage Vₜₕ, and/or

(g) combinations thereof.

The primary result of mismatched device physical dimensions is a mismatch in the electrical characteristics of the transistors such as threshold voltage. However, several other methods are available to modify a MOS device threshold voltage (including via its physical dimensions). These alterations include, but are not limited to, the following:

1) Modifying the implant under the gate dielectric by:

a. change in dose,

b. change in energy,

c. change in species, and/or

d. combinations of the above;

2) Modifying the gate dielectric thickness by:

a. nitrogen or other implant that affects dielectric growth rate,

b. mask, etch and regrowth of gate dielectric,

c. partial etch back of gate dielectric, and/or

d. combinations of the above.

The designer can render the circuit more robust to manufacturing variation or potential device degradation by combining some of the above mismatches such as:

(a) V_{th,MN1}>V_{th,MN2} and |V_{th,MP4}|>|V_{th,MP3}|,

(b) L_{MN1}>L_{MN2} and L_{MP4}>L_{MP3},

(c) W_{MN1}>W_{MN2} and W_{MP4}>W_{MP3}, and/or

(d) combinations of the above,

where L and W are respectively channel length and device width linear dimensions of their corresponding transistors.

As can be determined by the above combinations, one optimal method for improving a circuit's robustness can be accomplished by modifying diagonal elements of the unit cell, i.e., transistors MN1 260 and MP4 370 or MN2 350 and MP3 360.

As mentioned, the primary effect of these modifications to the unit cell yields an imbalance in the circuit that causes the SRAM to initialize to an established known state. Some of the unit cell combinations can be selected from which a designer could employ any of the above methods to modify the threshold voltage of the MOS devices to set the initialized value of the SRAM state as well as the simulation results from implementing the indicated modifications. Manufacturers/designers of SRAM circuits, or circuits with SRAM components, can utilize this method to build in specific code to be executed upon initialization of the product for built-in test (BIT), product validation, or many other uses for which early execution may be required or desired. The SRAM can contain a checksum or code that may be used to validate the operating system (OS) or application prior to loading into the electronic circuit.

The advantage of various exemplary embodiments is based on the prior knowledge of the state the SRAM initializes to upon power-up. Rather than being a purely random series of bits, the exemplary SRAM initializes to a specific state established by the designer. Such an initiation can be utilized in a manner that can be beneficial to the design of the product in which the SRAM is installed. In particular, the SRAM can store a default setting for initialization that can subsequently be overwritten, and afterwards be available as volatile memory in operations. By storing specific code, checksum data, or product validation data, the designer can incorporate this information at power-up to validate his design and make the end product more robust for his customer.

While certain features of the embodiments of the invention have been illustrated as described herein, many modifications, substitutions, changes and equivalents will now occur to those skilled in the art. It is, therefore, to be understood that the appended claims are intended to cover all such modifications and changes as fall within the true spirit of the embodiments.

1. A static random access memory (SRAM) for providing an initialization state and connecting to a plurality of signal lines including a bit line, an inverse bit line and a word line, said SRAM comprising:
a first inverter including a first n-type metal oxide semiconductor (MOS) transistor having a first n-type electrical characteristic and a first p-type MOS transistor having a first p-type electrical characteristic, said first transistors connecting respectively a first n-type drain and a first p-type drain together at a first junction that connects to the bit line;
a second inverter including a second n-type MOS transistor having a second n-type electrical characteristic and a second p-type MOS transistor having a second p-type electrical characteristic, said second transistors connecting respectively a second n-type drain and a second p-type drain together at a second junction that connects to the inverse bit line;
a voltage potential connecting to corresponding first and second p-type Sources of said first and second p-type MOS transistors; and
a ground potential connecting to corresponding first and second n-type sources of said first and second n-type MOS transistors, wherein
the SRAM initializes the bit line to a predetermined logical state of one of high and low in response to deliberate differences in said electrical characteristics between at least one of said first and second n-type MOS transistors and said first and second p-type MOS transistors.

2. The SRAM according to claim 1, wherein said electrical characteristic is threshold voltage.

3. The SRAM according to claim 2, wherein the SRAM initializes the bit line to logical high for at least one of said first n-type threshold voltage deliberately exceeding said second n-type threshold voltage, and absolute value of said second p-type threshold voltage deliberately exceeding absolute value of said first p-type threshold voltage.

4. The SRAM according to claim 2, wherein the SRAM initializes the bit line to logical low for at least one of said second n-type threshold voltage deliberately exceeding said first n-type threshold voltage, and absolute value of said first p-type threshold voltage deliberately exceeding absolute value of said second p-type threshold voltage.

5. The SRAM according to claim 1, wherein said electrical characteristic is ohmic resistance.

6. The SRAM according to claim 5, wherein the SRAM initializes the bit line to said logical high state for at least one of said first n-type resistance deliberately exceeding said second n-type resistance, and said second p-type resistance deliberately exceeding said first p-type resistance and low for at least one of said second n-type resistance deliberately exceeding said first n-type resistance, and said first p-type resistance deliberately exceeding said second p-type resistance.

7. The SRAM according to claim 1, wherein a first n-type gate and a first p-type gate connect at said second junction, and a second n-type gate and a second p-type gate connect at said first junction.

8. The SRAM according to claim 1, further comprising:
a third n-type MOS transistor connecting a third drain at said first junction, a third source at the bit line and a third gate at the word line; and
a fourth n-type MOS transistor connecting a fourth drain at said second junction, a fourth source at the inverse bit line and a fourth gate at the word line.

9. A static random access memory (SRAM) for providing an initialization state and connecting to a plurality of signal lines including a bit line, an inverse bit line and a word line, said SRAM comprising:
a first inverter including a first n-type metal oxide semiconductor (MOS) transistor having a first n-type threshold voltage and a first p-type MOS transistor having a first p-type threshold voltage, said first transistors connecting respectively a first n-type drain and a first p-type drain together at a first junction;
a second inverter including a second n-type MOS transistor having a second n-type threshold voltage and a second p-type MOS transistor having a second p-type threshold voltage, said second transistors connecting respectively a second n-type drain and a second p-type drain together at a second junction, wherein a first type gate and a first p-type gate connect at said second junction, and a second n-type gate and a second p-type gate connect at said first junction;
a voltage potential connecting to corresponding first and second p-type sources of said first and second p-type MOS transistors;
a ground potential connecting to corresponding first and second n-type sources of said first and second n-type MOS transistors;
a third n-type MOS transistor connecting a third drain at said first junction, a third source at the bit line and a third gate at the word line; and
a fourth n-type MOS transistor connecting a fourth drain at said second junction, a fourth source at the inverse bit line and a fourth gate at the word line, wherein
the SRAM initializes the bit line to a predetermined logical high state for at least one of said first n-type threshold voltage deliberately exceeding said second n-type threshold voltage, and absolute value of said second p-type threshold voltage deliberately exceeding absolute value of said first p-type threshold voltage, and
the SRAM initializes the bit line to a predetermined logical low state for at least one of said second n-type threshold voltage deliberately exceeding said first n-type threshold voltage, and absolute value of said first p-type threshold voltage deliberately exceeding absolute value of said second p-type threshold voltage.

10. The SRAM according to claim 9, wherein said electrical characteristics are one of threshold voltages and ohmic resistances.

11. A static random access memory (SRAM) for providing an initialization state and connecting to a plurality of signal lines including a bit line, an inverse bit line and a word line, said SRAM comprising:
a first inverter including a first n-type metal oxide semiconductor (MOS) transistor having a first n-type threshold voltage and a first p-type MOS transistor having a first p-type threshold voltage, said first transistors connecting respectively a first n-type drain and a first p-type drain together at a first junction that connects to the bit line;
a second inverter including a second n-type MOS transistor having a second n-type threshold voltage and a second p-type MOS transistor having a second p-type threshold voltage, said second transistors connecting respectively a second n-type drain and a second p-type drain together at a second junction that connects to the inverse bit line;
a voltage potential connecting to corresponding first and second p-type sources of said first and second p-type MOS transistors; and
a ground potential connecting to corresponding first and second n-type sources of said first and second n-type MOS transistors, wherein
the SRAM initializes the bit line to predetermined logical high for at least one of said first n-type threshold voltage deliberately exceeding said second n-type threshold voltage, and absolute value of said second p-type threshold voltage deliberately exceeding absolute value of said first p-type threshold voltage.

12. A static random access memory (SRAM) for providing an initialization state and connecting to a plurality of signal lines including a bit line, an inverse bit line and a word line, said SRAM comprising:
a first inverter including a first n-type metal oxide semiconductor (MOS) transistor having a first n-type threshold voltage and a first p-type MOS transistor having a first p-type threshold voltage, said first transistors connecting respectively a first n-type drain and a first p-type drain together at a first junction that connects to the bit line;
a second inverter including a second n-type MOS transistor having a second n-type threshold voltage and a second p-type MOS transistor having a second p-type threshold voltage, said second transistors connecting respectively a second n-type drain and a second p-type drain together at a second junction that connects to the inverse bit line;
a voltage potential connecting to corresponding first and second p-type sources of said first and second p-type MOS transistors; and
a ground potential connecting to corresponding first and second n-type sources of said first and second n-type MOS transistors, wherein
the SRAM initializes the bit line to predetermined logical low for at least one of said second n-type threshold voltage deliberately exceeding said first n-type threshold voltage, and absolute value of said first p-type threshold voltage deliberately exceeding absolute value of said second p-type threshold voltage.
